(19) United States
(12) Patent Application Publication
(10) Pub. No.: US 2009/0169719 A1
(43) Pub. Date: Jul. 2, 2009

(54) METHOD FOR PRINTING HIGH QUALITY IMAGES ON CURVED SUBSTRATES

(75) Inventor: Craig Orr, Novi, MI (US)

Correspondence Address: Brinks Hofer Gilson & Lione/Ann Arbor, 524 South Main Street, Suite 200, Ann Arbor, MI, 48104, US

(73) Assignee: Exatec LLC, Wixom, MI (US)

(21) Appl. No.: 12/346,159

(22) Filed: Dec. 30, 2008

Related U.S. Application Data
(60) Provisional application No. 61/018,145, filed on Dec. 31, 2007.

(51) Int. Cl. C23C 16/52

(52) U.S. Cl. 427/8

(57) ABSTRACT

A method for printing on the curved surface of a three-dimensional (3-D) article, such as a plastic window. The printing method generally comprises generating a 3-D surface with the desired image; defining print head paths; calculating imaginary, two-dimensional printing surfaces; projecting the desired image onto the imaginary, two-dimensional printing surfaces; inspecting and correcting for any missed portion of the projected image; calibrating and adjusting the projected image; and printing the projected image through the imaginary, two-dimensional printing surfaces, thereby, creating the desired image on the surface of the 3-D article.

### CROSS REFERENCE TO RELATED APPLICATION

This application claims the benefit of U.S. Provisional Application Ser. No. 61/018,145 filed on Dec. 31, 2007, entitled “METHOD FOR PRINTING HIGH QUALITY IMAGES ON CURVED SUBSTRATES,” the entire contents of which are incorporated herein by reference.

### FIELD

This invention relates generally to printing on a three-dimensional object. More specifically, this invention relates to a method of printing using an ink jet apparatus to apply a high quality image to a curved substrate.

### BACKGROUND

Molded plastic articles are becoming widely accepted as a replacement for metallic and glass articles. For example, polycarbonate plastic panels are currently being used to replace conventional glass windows and metal body panels in a variety of automotive applications. One advantage associated with molded plastic articles is the integration of several components into one article, thereby reducing the number of assembly operations. In other words, an article that previously was comprised of several components bonded or joined together may now be manufactured in a one step, molding operation. One inherent problem that has resulted from the advent of this practice is the limited ability to print an image upon the resulting complex (concave, convex, etc.) surface shape of the article. Printing is desirable since other means for creating images on the surface of complex three-dimensional articles are time consuming. Unfortunately, common two-dimensional printing methods, such as screen-printing and pad-printing, have been able to meet this need with only limited success.

Accordingly, there exists a need to provide improved methods for printing on three-dimensional articles. In particular there exists a need for more efficient and effective methods of printing high quality images onto curved substrates, such as plastic automotive windows.

### SUMMARY

In satisfying the above need, as well as overcoming the enumerated drawbacks and other limitations of the related art, the present invention generally provides a method for printing images onto the curved surface of three-dimensional articles, including but not limited to, automotive plastic windows. The printing method comprises generating a 3-dimensional (3-D) surface with the desired image; defining print head paths; calculating imaginary, two-dimensional printing surfaces; projecting the desired image onto said printing surfaces; inspecting and correcting for any missed or absent portions of the desired image in the projected image; calibrating and adjusting the projected image; and printing the projected image through the two-dimensional printing surfaces, thereby, creating the desired image on the surface of the 3-D article.

In one aspect of the present invention, the step of defining the print head paths uses a software program that defines the location of each nozzle on the print head in relation to the curved surface of the three-dimensional article. This software program may further include data related to the desired travel path for the print head including the location of each nozzle at multiple locations along the travel path.

In another aspect of the present invention, the imaginary, two-dimensional printing surfaces lie between the print head and the curved surface of the three-dimensional article. The projection of the desired image from the three-dimensional article onto the two-dimensional printing surfaces may result in a skewed image on the two-dimensional printing surfaces.

Further areas of applicability for the present invention will become apparent from the description provided herein. It should be understood that the description and specific examples are intended for purposes of illustration only and are not intended to limit the scope of the present invention.

### BRIEF DESCRIPTION OF THE DRAWINGS

The drawings described herein are for illustration purposes only and are not intended to limit the scope of the present invention in any way.

FIG. 1 is a flow chart depicting one method of printing an image on a three-dimensional article according to the teachings of the present invention;

FIG. 2A is a perspective view of the surface of a three-dimensional article upon which an image is being printed using a print head according to one embodiment of the present invention;

FIG. 2B is a perspective view of the underside of the print head of FIG. 2A exhibiting multiple nozzles through which the ink is jetted;

FIG. 2C is a side view of the print head of FIG. 2A taken generally along line A-A as it ejects ink on to the curved surface of a three-dimensional article;

FIG. 3A is a perspective view of a print head applying a skewed image through a series of imaginary two-dimensional printing surfaces on to the curved surface of a three-dimensional article according to the teachings of the present invention;

FIG. 3B is a side view of the print head of FIG. 3A applying an image to the curved surface of a three-dimensional article;

FIG. 4A is a schematic representation of an image as applied to a curved surface of a three-dimensional article according to the teachings of the present invention; and

FIG. 4B is a schematic representation of a skewed image that is applied by the print head to two-dimensional printing surfaces in order to create the image of FIG. 4A on the curved surface of a three-dimensional article.

### DETAILED DESCRIPTION

The following description is merely exemplary in nature and is in no way intended to limit the present invention or its application or uses. It should be understood that throughout the description and drawings, corresponding reference numerals indicate like or corresponding parts and features.

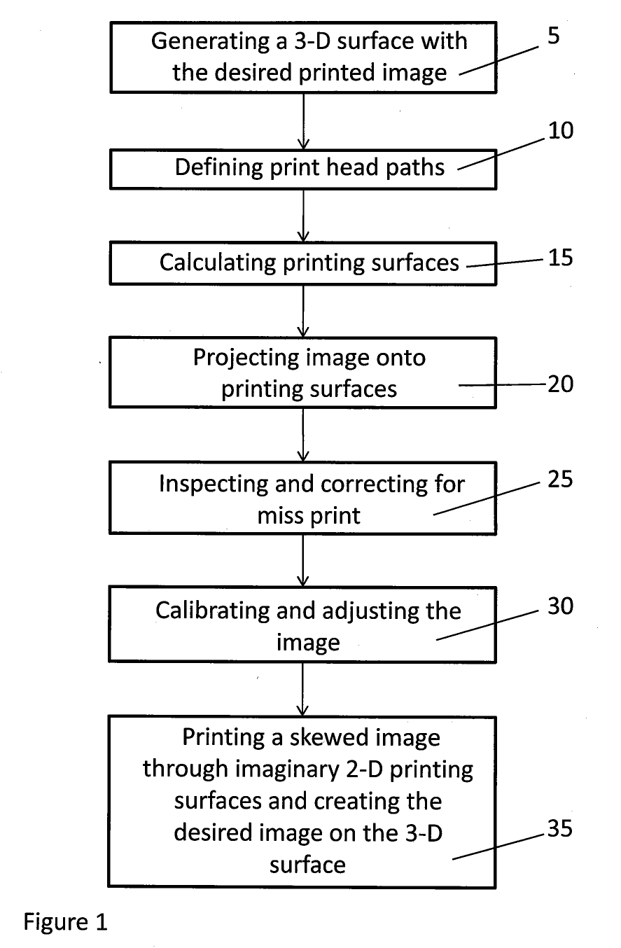

The present invention generally provides a method of printing on the surface of a three-dimensional (3-D) article or object. More specifically, this invention provides a method of printing a high quality image on to the curved surface of the article using an ink jet printing apparatus. Referring to FIG. 1, the printing method comprises the steps of: generating, at 5, a file being an electronic representation of the 3-D article with the desired image printed on the article's surface; defining, at 10, the path of the print head to be used for printing the image on the 3-D article; calculating, at 15, imaginary, two-dimensional printing surfaces where all nozzles of the print head are within a certain distance from said surface; projecting, at 20, the desired image from the curved surface of the article onto the imaginary, two-dimensional printing surfaces; inspecting, at 25, the projected image to ensure no portion of the desired image has been missed and correcting for any portion that is found to be absent; calibrating, at 30, and adjusting the projected image to match the desired image accordingly; and printing, at 35, the image by guiding the print head along a given path such that the print head is effectively printing the projected image through the imaginary printing surfaces, but the ink is actually landing on the article's curved surface, thereby, printing the desired image on the curved surface.

The printing method according to the various teachings of the present invention offers several advantages. The print head may be moved along the surface of the three-dimensional article, rather than in a single plane. This printing method does not rely on the nozzles or jets of the print head always being exactly in a projected plane, but instead within a range of distances relative to the projected plane. Thus, the printing method does not need to turn nozzles on/off in order to correct for the distance between a nozzle and the surface of the article.

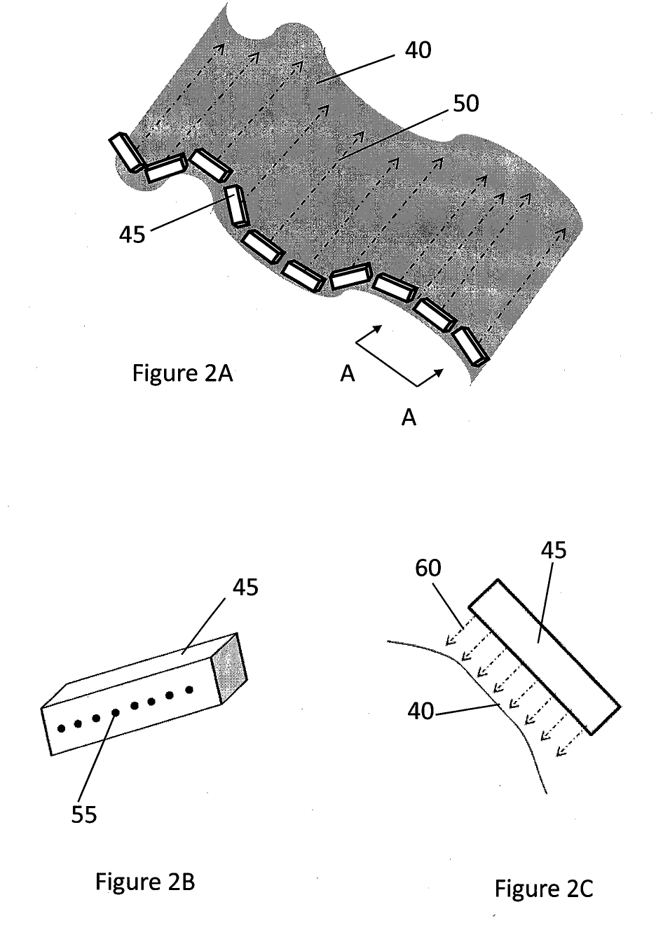

Referring to FIG. 2A, a three-dimensional article 40 is shown with simulated print heads 45 lined-up for printing an image onto the surface of the article 40. The direction in which the print head 45 scans the surface and applies the image in each subsequent pass 50 is shown. Although the multiple print heads 45 are simulated to be in-line in FIG. 2A, one print head 45 or multiple print heads 45 may be utilized for the printing of the image onto the curved surface of the 3-dimensional article 40. One skilled-in-the-art of printing will recognize that the printing of the image may be accomplished by moving the print head 45 or curved surface of the article 40 in any desired direction. A simplified view of the bottom of the print head 45 from FIG. 2A showing multiple nozzles 55 through which the ink is jetted or ejected is shown in FIG. 2B. Although eight nozzles 55 are shown with respect to the print head 45 of FIG. 2B, any other number of nozzles 55 may be incorporated and used in conjunction with the print head 45. In FIG. 2C, a side view of the print head 45 from FIG. 2A taken along line A-A is shown applying ink 60 to the curved surface of the article 40.

In the step of generating, at 5, a file comprising the three-dimensional article 40 with the desired image printed on the article's surface, one can either import into the file an existing computer-aided design (CAD) drawing of the 3-D article 40 with the desired image already shown on its surface or one can add the desired printed image to the article's surface in an existing CAD drawing of the 3-D article 40. It is also possible to initially create the entire CAD drawing of the article exhibiting the desired image.

The step of defining 10 the path of the print head 45 for use in printing the image on the 3-D article 40 can be accomplished by creating a software program that simulates a series of print heads 45. This series of print heads 45 are placed along the length of the 3-D article 40 in a manner that is best suited for printing the desired image onto the article 40 (see FIG. 2A). The location of each nozzle 55 of the print head 45 in relation to a point on the curved surface of the 3-D article 40 should be included in the data imported into the software program. In addition, data related to the desired travel path for the print head 45 should also be imported into the software program. The printing path 50 established for the print head 45 includes data describing a series of nozzle 55 positions and a corresponding set of image requirements with respect to each nozzle 55 and its location along the printing path 50.

The path traveled by the print head 45 may be represented by a single variable that defines either the center point of the print head 45 or that represents the line traveled by the outside or lateral nozzles 55 of the print head 45. This variable as defined by the outside line is preferred because it allows for variation in the orientation of the print head 45 during operation and provides for better correlation between the print head 45 and the printed image when changes occur in the orientation of the print head 45, e.g., during cornering. The software program should be able to calculate the location of each nozzle 55 at multiple locations in the path traveled by the print head 45. These calculations may be based on either the distance measured for a line extending from a nozzle 55 that is normal to the common plane between the nozzles 55 or that follows along a path established by the force of gravity to the surface of the article 40.

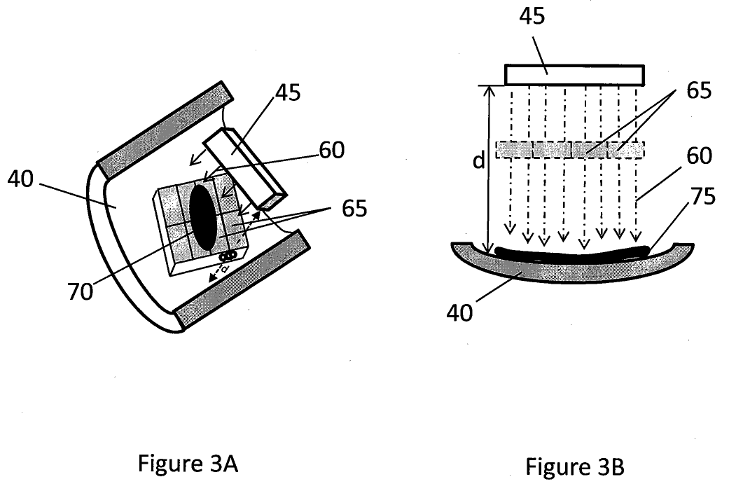

The step of calculating, at 15, an imaginary, two-dimensional printing surface through which the image may be printed can also be accomplished using a software program. This software program may calculate the distance from the nozzle to the surface of the 3-D article for every nozzle position in a given printing path. If each nozzle position is geometrically defined as a point, then a point cloud is created where the distance between the curved surface of the 3-D article and each selected point is within the maximum stand-off range determined for the desired or selected combination of the print head 45 and ink formulation 60. The maximum stand-off range or distance may be determined experimentally or provided by the manufacturer of the ink 60 and print head 45. The collection of points or point cloud representing the stand-off range determined for the entire path of the print head 45 is used to provide a boundary for the location of a series of imaginary, two-dimensional printing surfaces 65 as shown in FIGS. 3A and 3B. In FIG. 3B, the path of the print head 45 is shown to be a distance, d, away from the 3-dimensional article 40. In essence, the collection of imaginary, two-dimensional printing surfaces 65 lie between the print head 45 and the curved surface of the 3-dimensional article 40 that is to be printed. The distance, d, between the curved surface of the 3-D article 40 and the print head 45 is given by the known stand-off distance for the print head 45 and ink 60 combination.

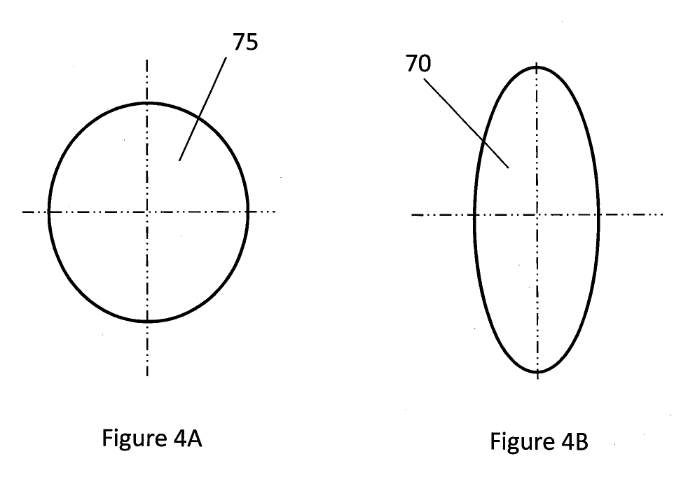

Once the imaginary, two-dimensional printing surfaces 65 are established, it is possible to perform the step of projecting 20 the desired image from the curved surface of the 3-D article 40 onto these newly created imaginary, two-dimensional printing surfaces 65. The image 75 as printed on the curved surface of the 3-D article 40 may become skewed or look differently when projected onto the imaginary, two-dimensional printing surfaces 65. For example, a circular image 75 as printed on the surface of a 3-D article 40 (FIG. 4A) may resemble an oval image 70 when projected onto the 2-D printing surfaces 65 (FIG. 4B). The skewed image 75 occurs due to the software taking into account differences in distances caused by the degree of curvature associated with the article 40. Modulating the drop size of the ink 60 ejected from a nozzle 55 may compensate for this curvature or the difference encountered in the “flight” time required for an ink droplet to travel the distance between the print head 45 and the curved surface of the 3-D article 40.

After the printing surfaces 65 have been established, it is a simple process for one to determine if any portions of the desired image 70 have not been properly projected onto a corresponding printing surface 65. An operator can perform the step of inspecting 25 the projected image 75 to ensure that no portion of the image has been missed. The operator can also correct for any portion of the projected image 75 that is determined to be absent. This inspection and correction step 25 can be accomplished either manually or through the use of various software algorithms. After all missing or absent portions of the projected image 75 have been accounted for on the imaginary, two-dimensional printing surfaces 65, the printing path 50 established for the print head 45 should include a complete set of nozzle 55 positions and a corresponding set of image requirements with respect to each nozzle 55 and location along the printing path 50.

During execution of the software program, a robotic interface can provide firing signals to an ink jet or print head controller. The actual pathway executed by the robot will need to be correlated with the printing path 50 for the print head 45 determined from the CAD drawings. The appropriate positions for the print head 45 throughout the entire robot's pathway will need to be logged. These logged input positions can be used in the step of calibrating 30 the CAD diagrams to the real world application and in adjusting the image accordingly. Appropriate execution relies upon the actual location of the print head 45 and 3-D article 40 in relation to each other or to some pre-defined coordinate system, such as the printing surface 65. Actual calibration can accomplished by physical measurement, optical measurement, or by using the basic frame coordinates determined by the robotic system.

The step of printing 35 is accomplished by guiding the print head 45 along a given path 50 such that the print head 45 is effectively printing a skewed image 75 through the imaginary, two-dimensional printing surfaces 65. In this step, the ink 60 actually lands on the 3-D article's surface 40, thereby, creating the desired image 70. In other words, the print head 45 attempts to print the skewed image 75 onto the imaginary, two-dimensional printing surfaces 65, but the ink actually lands on the 3-D article 40 creating the actual desired image 70.

The print head 45 may be held and moved by any robotic system known to one skilled-in-the-art. Such a robotic system may include a robot arm that is mounted in a stationary manner to a support surface, and a print head 45 attached to the end of the robot arm. A controller may be electrically coupled to the robot arm and the print head 45 with the print head 45 being fluidly coupled to a reservoir of ink 60. The robot arm is articulatable and capable of moving the print head 45 near any desired point on the surface of the article 40 that is to be printed with the desired image 75.

The selected ink 60 formulation needs to be compatible with the selected print head 45. One skilled-in-the-art will recognize that the type of ink 60 and the ink parameters, including but not limited to, percent solids, particle distributions, rheological properties, and cure characteristics need to be selected to match the operating parameters associated with the print head 45, such as nozzle orifice size, operating temperature, and pressure gradient.

The three-dimensional articles 40 upon which the desired image 75 is printed may be comprised of any materials, including metals, glass, and plastics. The plastic materials may include any thermoplastic polymeric resin or a mixture or combination thereof. Appropriate thermoplastic resins include, but are not limited to, polycarbonate resins, acrylic resins, polyarylate resins, polyester resins, and polysulfone resins, as well as copolymers and mixtures thereof. The three-dimensional article 40 may be created using any technique known to one skilled-in-the-art, including but not limited to molding and thermoforming.

It is another objective of the present invention to provide a method of printing an image onto substantially transparent, plastic windows and panels that are 3-dimensional or that have a curved surface upon which a printed image is to be applied. Thus plastic windows represent a specific type of three-dimensional article 40. Such panels or windows may be formed through the use of any of the various known techniques, such as molding, thermoforming, or extrusion. The desired image 75 printed on the windows may include but not be limited to a black-out border, a fade-out border, a logo, and regulatory markings.

In its final construction, the plastic window or other finished 3-D article 40 may be protected from such natural occurrences as exposure to ultraviolet radiation, oxidation, and abrasion through the use of a single protective layer or multiple protective layers. The protective layers may be a plastic film, an organic coating, an inorganic coating, or a mixture thereof. The film and coatings may comprise ultraviolet absorber (UVA) molecules, rheology control additives, such as dispersants, surfactants, and transparent fillers (e.g., silica, aluminum oxide, etc.) to enhance abrasion resistance, as well as other additives to modify optical, chemical, or physical properties. The protective coatings may be applied by any suitable technique known to those skilled in the art. These techniques include deposition from reactive species, such as those employed in vacuum-assisted deposition processes, and atmospheric coating processes, such as those used to apply sol-gel coatings to substrates. Examples of vacuum-assisted deposition processes include but are not limited to plasma enhanced chemical vapor deposition, ion assisted plasma deposition, magnetron sputtering, electron beam evaporation, and ion beam sputtering. Examples of atmospheric coating processes include but are not limited to curtain coating, spray coating, spin coating, dip coating, and flow coating.

The foregoing description of various embodiments of the invention has been presented for purposes of illustration and description. It is not intended to be exhaustive or to limit the invention to the precise embodiments disclosed. Numerous modifications or variations are possible in light of the above teachings. The embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A method for printing a desired image on a curved surface of a three-dimensional article, the method comprising the steps of
generating a file of the three-dimensional article with the desired image on the curved surface of the article;
defining a path of a print head having multiple nozzles to be used for printing the image using an ink onto the three-dimensional article; the nozzles of the print head being within a predetermined distance from the curved surface of the three-dimensional article;
calculating multiple points along the path that define a series of imaginary, two dimensional printing surfaces;
projecting the desired image from the curved surface of the article onto the imaginary, two-dimensional printing surfaces;
inspecting the projected image on the printing surfaces to ensure that no portion of the desired image has been missed and correcting for any portion that is found to be absent;
calibrating and adjusting the projected image to match the desired image; and
printing the image by guiding the print head along the given path such that the print head is effectively printing the projected image through the imaginary, two-dimensional printing surfaces with the ink actually landing on the curved surface of the three-dimensional article and creating the desired image thereon.

2. The method of claim 1, wherein the step of generating the file uses a computer-aided design drawing of the 3-dimensional article with the desired image provided on its surface.

3. The method of claim 1, wherein the step of defining the path of the print head uses a software program that defines the location of each nozzle on the print head in relation to the curved surface of the three-dimensional article.

4. The method of claim 3, wherein the software program further includes data related to the desired travel path for the print head.

5. The method of claim 4, wherein the travel path represents a single variable defined as one selected from the group of the center point of the print head and the line traveled by the lateral nozzles of the print head.

6. The method of claim 4, wherein the software program calculates the location of each nozzle at multiple locations in the travel path.

7. The method of claim 6, wherein the calculation is based on the distance measured for a line that is normal to the common plane between the nozzles to the surface of the article.

8. The method of claim 6, wherein the calculation is based on the distance measured for a line extending from a nozzle to the surface of the article that follows the path established by the force of gravity.

9. The method of claim 1, wherein in the step of calculating the imaginary, two-dimensional printing surfaces, the predetermined distance between the nozzle and the curved surface of the three-dimensional article is within the maximum stand-off range determined for the selected combination of print head and ink formulation.

10. The method of claim 1, wherein the imaginary, two-dimensional printing surfaces lie between the print head and the curved surface of the three-dimensional article.

11. The method of claim 1, wherein the step of projecting the desired image from the three-dimensional article onto the imaginary, two-dimensional printing surfaces results in a skewed image on the imaginary, two-dimensional printing surfaces.

12. The method of claim 1, wherein the step of inspecting and adjusting the projected image is accomplished either manually or through the use of software algorithms.

13. The method of claim 1, wherein the step of defining the path of a print head provides a printing path that includes a series of nozzle positions and a corresponding set of image requirements with respect to each nozzle and its location.

14. The method of claim 1, wherein the step of calibrating and adjusting the projected image relies upon the actual location of the print head and the three-dimensional article in relation to each other or to the printing surface.

15. The method of claim 1, wherein the step of printing includes manipulation of the print head using a robotic system.

16. A method for printing an image on a curved surface of a plastic window, the method comprising the steps of
generating a file of the window with the desired image on its curved surface;
defining a path of a print head having multiple nozzles to use for printing the image with an ink onto the window; the nozzles of the print head being within a predetermined distance from the curved surface of the window;
calculating multiple points along the path that define a series of imaginary, two dimensional printing surfaces;
projecting the desired image from the curved surface of the window onto the imaginary, two-dimensional printing surfaces;
inspecting the projected image on the imaginary, two-dimensional printing surfaces to ensure that no portion of the desired image has been missed and correcting for any portion that is found to be absent;
calibrating and adjusting the projected image to match the desired image; and
printing the image by guiding the print head along the given path such that the print head is effectively printing the projected image through the imaginary, two-dimensional printing surfaces with the ink actually landing on the curved surface of the window and creating the desired image thereon.

17. The method of claim 16, wherein the desired image is one selected from the group of a black-out border, a fade-out border, a logo, and regulatory markings.

18. The method of claim 16, wherein the step of generating the file uses a computer-aided design drawing of the window with the desired image provided on its surface.

19. The method of claim 16, wherein the step of defining the path of the print head uses a software program that defines the location of each nozzle on the print head in relation to the curved surface of the window.

20. The method of claim 19, wherein the software program calculates the location of each nozzle at multiple locations in the travel path.

21. The method of claim 16, wherein in the step of calculating the imaginary, two-dimensional printing surfaces, the predetermined distance between the nozzle and the curved surface of the three-dimensional article is within the maximum stand-off range determined for the selected combination of print head and ink formulation.

22. The method of claim 16, wherein the imaginary, two-dimensional printing surfaces lie between the print head and the window's curved surface.

23. The method of claim 16, wherein the step of projecting the desired image from the window onto the imaginary, two-dimensional printing surfaces results in a skewed image on the imaginary, two-dimensional printing surfaces.

24. The method of claim 16, wherein the step of calibrating and adjusting the projected image relies upon the actual location of the print head and the window in relation to each other or to the printing surface.

25. The method of claim 16, wherein the step of printing includes manipulation of the print head using a robotic system.
